(19) United States
(12) Patent Application Publication
(10) Pub. No.: US 2017/0162715 A1
(43) Pub. Date: Jun. 8, 2017

(54) THIN FILM TRANSISTOR AND METHOD OF MANUFACTURING THE SAME

(71) Applicant: Japan Display Inc., Minato-ku (JP)

(72) Inventors: Takashi OKADA, Tokyo (JP); Masayoshi FUCHI, Tokyo (JP); Hajime WATAKABE, Tokyo (JP); Akihiro HANADA, Tokyo (JP)

(73) Assignee: Japan Display Inc., Minato-ku (JP)

(21) Appl. No.: 15/371,897

(22) Filed: Dec. 7, 2016

(30) Foreign Application Priority Data
Dec. 7, 2015 (JP) 2015-238658
Dec. 7, 2015 (JP) 2015-238672

(51) Int. Cl. H01L 29/786; H01L 27/12; H01L 21/477; H01L 29/24; H01L 29/66; H01L 21/02

(52) U.S. Cl. CPC H01L 29/78696; H01L 29/66969; H01L 21/02565; H01L 21/02631; H01L 21/477; H01L 29/24; H01L 29/7869; H01L 27/1225; G02F 1/1368

(57) ABSTRACT

According to one embodiment, a method of manufacturing a thin film transistor, includes forming an island-like first insulating layer containing oxygen above an insulating substrate, forming an oxide semiconductor layer above the insulating substrate and the first insulating layer and in contact with the first insulating layer, and performing heat treatment to supply oxygen from the first insulating layer to an overlapping area of the oxide semiconductor layer, which is overlaid on the first insulating layer.

### CROSS-REFERENCE TO RELATED APPLICATIONS

This application is based upon and claims the benefit of priority from Japanese Patent Applications No. 2015-238658, filed Dec. 7, 2015; and No. 2015-238672, filed Dec. 7, 2015, the entire contents of all of which are incorporated herein by reference.

### FIELD

Embodiments described herein relate generally to a thin film transistor and a method of manufacturing the thin film transistor.

### BACKGROUND

Thin film transistors which employ oxide semiconductors for the semiconductor layers have been developed so as to be applied to display devices such as liquid crystal displays, or various control circuits. The electrical characteristics of such thin film transistors are affected by the oxygen concentration in the semiconductor layer. For example, some of oxygen defects in the oxide semiconductor layer act as donors to release electrons as a carrier. Therefore, if an oxygen defect is created in a channel region of a thin film transistor including an oxide semiconductor layer, the resistance of the channel region decreases and the threshold voltage is shifted in a negative direction. That is, the variation in the oxygen concentration in an oxide semiconductor causes variation in the threshold of the thin film transistor. However, it is difficult to control the oxygen concentration in an oxide semiconductor layer during the formation thereof.

### BRIEF DESCRIPTION OF THE DRAWINGS

FIG. 1 is a cross section schematically showing an example of the thin film transistor according to the first embodiment.

FIG. 2 is a sectional view of the thin film transistor shown in FIG. 1, illustrating an example of its manufacturing method.

FIG. 3 is a sectional view illustrating a step which follows that shown in FIG. 2.

FIG. 4 is a sectional view illustrating a step which follows that shown in FIG. 3.

FIG. 5 is a sectional view of the thin film transistor shown in FIG. 1, illustrating another example of its manufacturing method.

FIG. 6 is a cross-section schematically showing an example of the thin film transistor according to the second embodiment.

FIG. 7 is a sectional view of the thin film transistor shown in FIG. 6, illustrating an example of its manufacturing method.

FIG. 8 is a sectional view illustrating a step which follows that shown in FIG. 7.

FIG. 9 is a sectional view illustrating a step which follows that shown in FIG. 8.

FIG. 10 is a cross section schematically showing an example of the thin film transistor according to the third embodiment.

FIG. 11 is a sectional view of the thin film transistor shown in FIG. 10, illustrating an example of its manufacturing method.

FIG. 12 is a sectional view illustrating a step which follows that shown in FIG. 11.

FIG. 13 is a sectional view illustrating a step which follows that shown in FIG. 12.

FIG. 14 is a circuit diagram showing a structure example of a display device to which a thin film transistor according to these embodiments is applied.

FIG. 15 is a sectional view showing another example of the thin film transistor shown in FIG. 1.

### DETAILED DESCRIPTION

In general, according to one embodiment, there is provided a method of manufacturing a thin film transistor, comprising: forming an island-like first insulating layer containing oxygen above an insulating substrate; forming an oxide semiconductor layer above the insulating substrate and the first insulating layer and in contact with the first insulating layer; and performing heat treatment to supply oxygen from the first insulating layer to an overlapping area of the oxide semiconductor layer, which is overlaid on the first insulating layer.

According to another one embodiment, there is provided a method of manufacturing a thin film transistor, comprising: forming a first insulating layer of an oxide or an oxynitride above an insulating substrate; forming, above the first insulating layer, a resist layer including an opening; implanting oxygen ions to the first insulating layer using the resist layer as a mask; forming an oxide semiconductor layer on the first insulating layer after removing the resist layer; and performing heat treatment to supply oxygen from the first insulating layer to the oxide semiconductor layer.

According to still another one embodiment, there is provided a thin film transistor comprising: an island-like first insulating layer provided above an insulating substrate; an oxide semiconductor layer located above the insulating substrate and the first insulating layer and being in contact with the first insulating layer; a second insulating layer provided on the oxide semiconductor layer; and a gate electrode provided on the second insulating layer, the oxide semiconductor layer comprising a channel region provided on the first insulating layer, and a source region and a drain region interposing the channel region therebetween.

Embodiments will be described hereinafter with reference to the accompanying drawings. Incidentally, the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc. of the respective parts are schematically illustrated in the drawings, compared to the actual modes. However, the schematic illustration is merely an example, and adds no restrictions to the interpretation of the invention. Besides, in the specification and drawings, the structural elements having functions, which are identical or similar to the functions of the structural elements described in connection with preceding drawings, are denoted by like reference numerals, and an overlapping detailed description is omitted unless otherwise necessary.

### First Embodiment

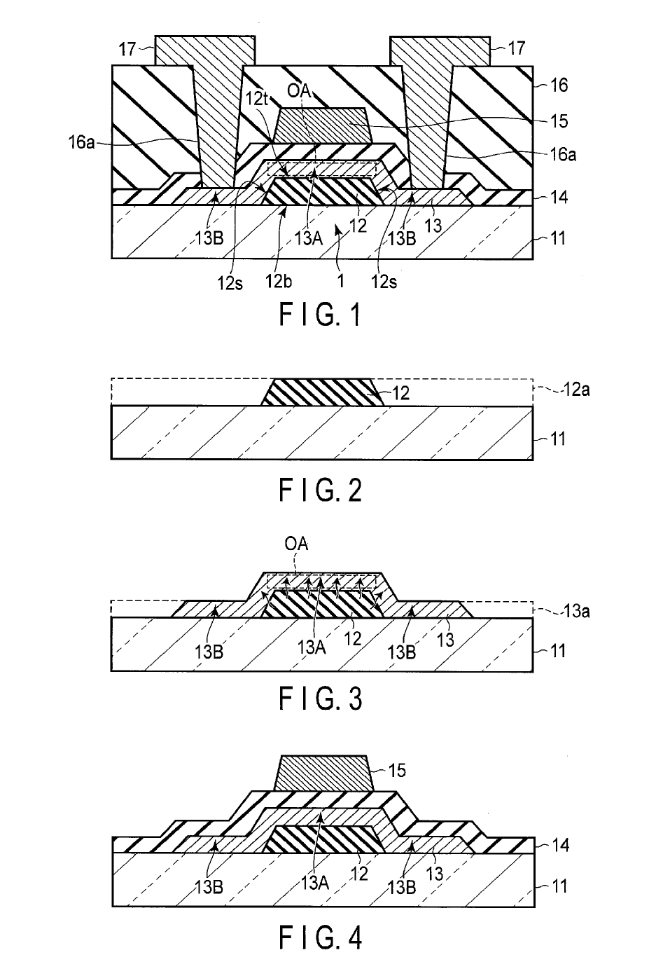

FIG. 1 is a sectional view schematically showing a structure example of a thin film transistor 1 according to the first embodiment. The thin film transistor 1 is of, for example, the top-gate n-channel type, and includes a semiconductor layer 13, a gate electrode 15 and source/drain electrodes 17 and 17, formed on an insulating substrate (to be referred to as a substrate hereafter) 11.

The substrate 11 is formed of, for example, a transparent insulating material such as glass. On the substrate 11, an island-shaped first insulating layer 12 of, for example, silicon oxide is formed. The first insulating layer 12 includes a top surface 12t, a bottom surface 12b, and side surfaces 12s. In the illustrated example, the bottom surface 12b is in contact with the substrate 11. The first insulating layer 12 functions as an oxygen supply source which releases oxygen by heat, which will be described later. The first insulating layer 12 should only be formed from an oxygen-containing material and may be formed from oxides other than silicon oxide, such as aluminum oxide and the like.

On the substrate 11, an oxide semiconductor layer (to be referred to as a semiconductor layer hereinafter) 13 is formed to cover the first insulating layer 12. The semiconductor layer 13 is a semiconductor layer made from an oxide of at least one of indium (In), gallium (Ga) and zinc (Zn), for example.

The semiconductor layer 13 is located above the substrate 11 and the first insulating layer 12, and is in contact with the first insulating layer 12. More specifically, the semiconductor layer 13 is in contact with the top surface 12t and the side surfaces 12 of the first insulating layer 12. Further, in the area where the first insulating layer 12 is not formed, the semiconductor layer 13 is in contact with the substrate 11.

The oxygen concentration of a portion of the semiconductor layer 13 which is in contact with the first insulating layer 12 is higher than that of a portion thereof, which is in contact with the substrate 11. In other words, oxygen is supplied from the first insulating layer 12 to an overlapping area OA of the semiconductor layers 13, which is overlaid thereon, thus forming a channel region 13A which has a high resistance. In areas of the semiconductor layer 13 which are not overlaid on the first insulating layer 12 (that is, non-overlaid areas), source/drain regions 13B and 13B are formed, which have oxygen concentration lower than that of the channel regions 13A and therefore have low resistance. The source region 13B and the drain region 13B sandwich the channel region 13A therebetween.

On the channel region 13A of the semiconductor layer 13, a gate electrode 15 is formed via a second insulating layer (gate insulating layer) 14. In the illustrated example, the second insulating layer 14 is formed further on the substrate 11 while covering the semiconductor layer 13. The second insulating layer 14 is formed from, for example, an oxide such as silicon oxide. On the gate electrode 15 and the second insulating layer 14, a third insulating layer 16 is formed to cover these. The third insulating layer 16 and the second insulating layer 14 include contact holes 16a and 16a which expose the source/drain regions 13B of the semiconductor layer 13. In the contact holes 16a and 16a, source/drain electrodes 17 and 17 are formed to be connected respectively to the source/drain regions 13B and 13B.

Note that the second insulating layer 14 is formed of an oxide or the like, which can function as an oxygen supply source, and with this structure, oxygen is supplied to the channel region 13A from the oxygen supply sources provided thereabove and therebelow. Therefore, as compared to the case where the second insulating layer 14 does not have a function as an oxygen supply source, the oxygen concentration of the channel region 13A, and the resistance thereof can be made higher.

Next, a method of manufacturing the thin film transistor 1 shown in FIG. 1 will now be described with reference to FIGS. 2 to 4.

As shown in FIG. 2, the first insulating layer 12 containing oxygen is formed on the substrate 11 of, for example, glass. More specifically, a silicon oxide layer 12a is formed on an entire surface of the substrate 11 by, for example, a chemical vapor deposition method (CVD). Subsequently, the silicon oxide layer 12a is etched by, for example, a lithography process, to form the first insulating layer 12 of an island shape, for example. The first insulating layer 12 is formed in a position corresponding to a position where the channel region 13A of the thin film transistor 1 is formed.

The oxygen concentration of the first insulating layer 12 is controlled by the film formation conditions at the time when the silicon oxide layer 12a is formed on the entire surface of the substrate 11 by the CVD. For example, the first insulating layer 12 is formed to have an oxygen concentration higher than that of the semiconductor layer 13, which will be described later.

Next, as shown in FIG. 3, a semiconductor layer 13a of an oxide, for example, at least one of indium (In), gallium (Ga) and zinc (Zn) is formed all over the substrate 11 using, for example, a sputtering method. The sputtering is performed under an inert gas atmosphere, for example.

Thereafter, the semiconductor layer 13a formed form the oxide is etched to form the semiconductor layer 13 patterned into, for example, an island shape which covers the first insulating layer 12. The semiconductor layer 13 includes a region in contact with the substrate 11 and a region in contact with the first insulating layer 12.

Next, the semiconductor layer 13 is subjected to heat treatment. Thus, oxygen contained in the first insulating layer 12 is supplied to the overlapping area OA of the semiconductor layers 13, which is in contact with the first insulating layer 12. Therefore, the oxygen defect in the oxide semiconductor layer 13 is supplemented, thereby making it possible to form the channel region 13A having high oxygen concentration and high resistance.

On the other hand, the diffusion coefficient of oxygen in the glass-made substrate 11 is smaller as compared to that in the first insulating layer 12. For this reason, the amount of oxygen supplied to the semiconductor layer 13 from the substrate 11 is small. Therefore, in the areas of the semiconductor layer 13, which are in contact with the substrate 11, the rate of supplement for the oxygen defect in the semiconductor layer 13 is low as compared to the overlapping area OA. As a result, the source/drain regions 13B and 13B having an oxygen concentration and resistance lower than those of the channel region 13A are formed in the areas of the semiconductor layer 13 which are in contact with the substrate 11.

Note that the heat treatment in the process shown in FIG. 3 may be omitted. That is, if sufficient oxygen can be supplied from the first insulating layer 12 to the channel region 13A of the semiconductor layer 13 with heat which may be applied in a step following the process shown in FIG. 3, the heat treatment shown in FIG. 3 may be omitted.

Next, as shown in FIG. 4, a silicon oxide layer, for example, is deposited all over the substrate 11 using, for example, CVD, thereby forming the second insulating layer 14 as a gate insulating layer. Thereafter, the gate electrode 15 is formed on the area where the first insulating layer 12 is formed, that is, on the area of the second insulating layer 14 which overlaid on the channel region 13A.

Next, as shown in FIG. 1, for example, a silicon oxide layer is deposited all over the substrate 11 using, for example, CVD, to form the third insulating layer 16. Then, the contact holes 16a and 16a are formed in through the third insulating layer 16 and the second insulating layer 14 so as to correspond to the source/drain regions 13B and 13B. As the source/drain electrodes 17 and 17 are formed in the contact holes 16a and 16a, respectively, the thin film transistor 1 shown in FIG. 1 is manufactured.

According to this embodiment, the first insulating layer 12 containing oxygen is formed in the region of the substrate 11, which corresponds to the channel region 13A, and the semiconductor layer 13 of an oxide is formed to be in contact with the substrate 11 and the first insulating layer 12. With this structure, oxygen is selectively supplied from the first insulating layer 12 to the semiconductor layer 13 by heat treatment. In this manner, the oxygen defect in the semiconductor layer 13 can be selectively supplemented, and therefore the channel region 13A having a necessary and sufficient resistance can be formed.

Further, the concentration of oxygen contained in the first insulating layer 12 is controlled, for example, when forming the first insulating layer 12, and also the concentration of oxygen supplied from the first insulating layer 12 to the semiconductor layer 13 is controlled by heat treatment. In this manner, the oxygen concentrations of the channel region 13A, and the source/drain regions 13B and 13B of the semiconductor layer 13 can be reliably controlled. Therefore, it is possible to reduce the variation in electrical characteristics including the threshold voltage of the thin film transistor.

### Modified Example

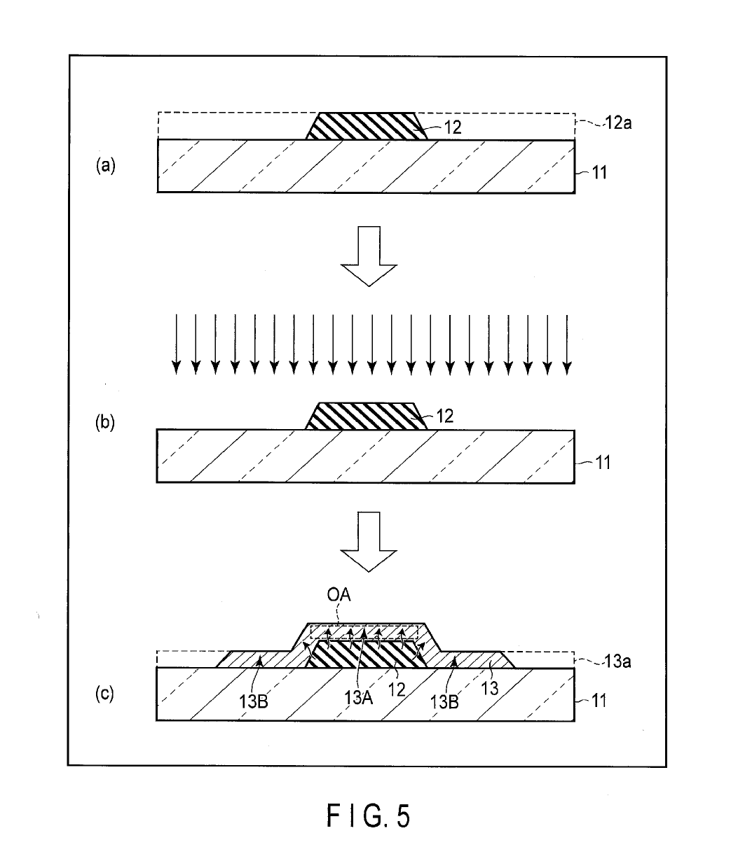

FIG. 5 shows another example of the method of manufacturing the thin film transistor 1 shown in FIG. 1.

As shown in FIG. 5(a), the first insulating layer 12 is formed on the substrate 11. FIG. 5(a) corresponds to FIG. 2 described above. In this modified example, the first insulating layer 12 may be formed from an oxide such as silicon oxide or aluminum oxide, or from an oxynitride such as silicon oxynitride or aluminum oxynitride. The rest of the structure here is the same as that of FIG. 2, and the explanation therefor will be omitted.

Next, as shown in FIG. 5(b), oxygen ions are implanted to the first insulating layer 12 and the substrate 11 using, for example, an ion implantation method. Thus, the first insulating layer 12 becomes an oxygen excess region which has an oxygen concentration higher than that of the semiconductor layer 13, which will be described later.

Note that the implantation of oxygen ions may be performed before the etching of the silicon oxide layer 12a. In other words, the silicon oxide layer 12a may be etched to form the island-shaped first insulating layer 12, after forming the silicon oxide layer 12a on the entire surface of the substrate 11 and implanting oxygen ions thereinto.

Thereafter, as shown in FIG. 5(c), the semiconductor layer 13 is formed and then subjected to heat treatment. FIG. 5(c) is the same as FIG. 3, and therefore its explanation will be omitted.

According to this example, the first insulating layer 12 is formed in the region on the substrate 11, which corresponds to the channel region 13A, and oxygen ions are implanted to the first insulating layer 12. Then, the semiconductor layer 13 of an oxide is formed to be in contact with the substrate 11 and the first insulating layer 12, and oxygen is selectively supplied to the semiconductor layer 13 from the first insulating layer 12 by heat treatment. In this manner, the oxygen defect in the semiconductor layer 13 can be selectively supplemented, and the channel region 13A which has a necessary and sufficient resistance can be formed.

Further, the concentration of oxygen ions implanted to the first insulating layer 12 is controlled and also the concentration of oxygen supplied from the first insulating layer 12 to the semiconductor layer 13 is controlled by heat treatment. In this manner, the oxygen concentrations of the channel region 13A and the source/drain regions 13B and 13B of the semiconductor layer 13 can be reliably controlled. Therefore, it is possible to reduce the variation in electrical characteristics including the threshold voltage of the thin film transistor.

### Second Embodiment

In the first embodiment, the first insulating layer 12 as an oxygen supply source is formed selectively on the substrate 11 of glass, for example, and the semiconductor layer 13 is formed on the first insulating layer 12 and the substrate 11.

By contrast, in the second embodiment, a nitride insulating layer of a nitride is formed on an entire surface of a substrate 11 and a first insulating layer of an oxide as an oxygen supply source is selectively formed on the nitride insulating layer. The semiconductor layer 13 is formed on the first insulating layer and the nitride insulating layer.

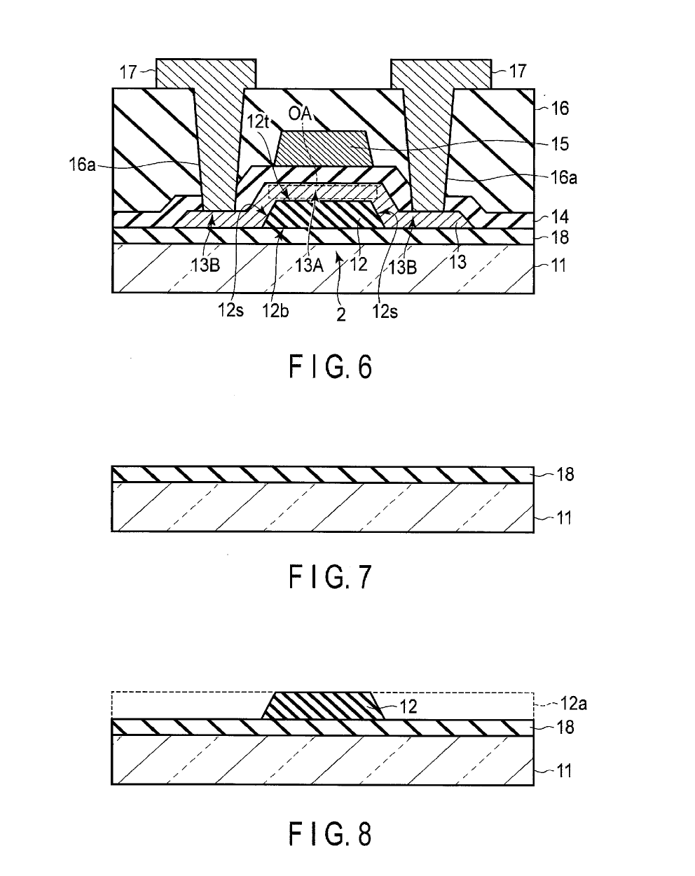

FIG. 6 is a sectional view schematically showing a structure example of a thin film transistor 2 according to the second embodiment.

As shown in FIG. 6, a nitride insulating layer 18 of, for example, silicon nitride is formed on the entire surface of the substrate 11. The nitride insulating layer 18 has a function of taking oxygen in from the semiconductor layer 13, which is formed on the nitride insulating layer 18, for reduction thereof, as will be described later.

On the nitride insulating layer 18, an island-shaped first insulating layer 12 of, for example, silicon oxide is formed. In other words, a bottom surface 12b of the first insulating layer 12 is in contact with the nitride insulating layer 18. Note that the first insulating layer 12 may be formed from an oxide insulating material other than silicon oxide, such as aluminum oxide.

On the nitride insulating layer 18, a semiconductor layer 13 is formed so as to cover the first insulating layer 12. The semiconductor layer 13 is in contact with a top surface 12t and side surfaces 12s of the first insulating layer 12, and in the region where the first insulating layer 12 is not formed, the semiconductor layer 13 is in contact with the nitride insulating layer 18. The oxygen concentration of the portion of the semiconductor layer 13, which is in contact with the first insulating layer 12 is higher than that of the portion in contact with the nitride insulating layer 18. In other words, oxygen is supplied from the first insulating layer 12 to the overlapping area OA of the semiconductor layers 13, which is overlaid on the first insulating layer 12, thus forming the channel region 13A having an enhanced resistance. In the region of the semiconductor layer 13, which is in contact with the nitride insulating layer 18, oxygen is taken into the nitride insulating layer 18, and thus the source/drain regions 13B and 13B having a resistance lower than that of the channel region 13A are formed. The other structure is the same as that of the first embodiment, the explanation therefor will be omitted.

Next, with reference to FIGS. 7 to 9, a method of manufacturing the thin film transistor 2 shown in FIG. 6 will be described.

As shown in FIG. 7, the nitride insulating layer 18 of, for example, silicon nitride is formed on an entire surface of the substrate 11 of, for example, glass by the CVD method, for example.

Next, as shown in FIG. 8, the first insulating layer 12 of oxide is formed on the nitride insulating layer 18. That is, a silicon oxide layer 12a is formed on an entire surface on the nitride insulating layer 18 using, for example, the CVD. Subsequently, a lithography process, for example, is carried out, and thereafter, the silicon oxide layer 12a is etched, thereby forming the island-like first insulating layer 12. The position where the first insulating layer 12 is formed corresponds to that of the region where the channel region 13A of the thin film transistor 2 is formed.

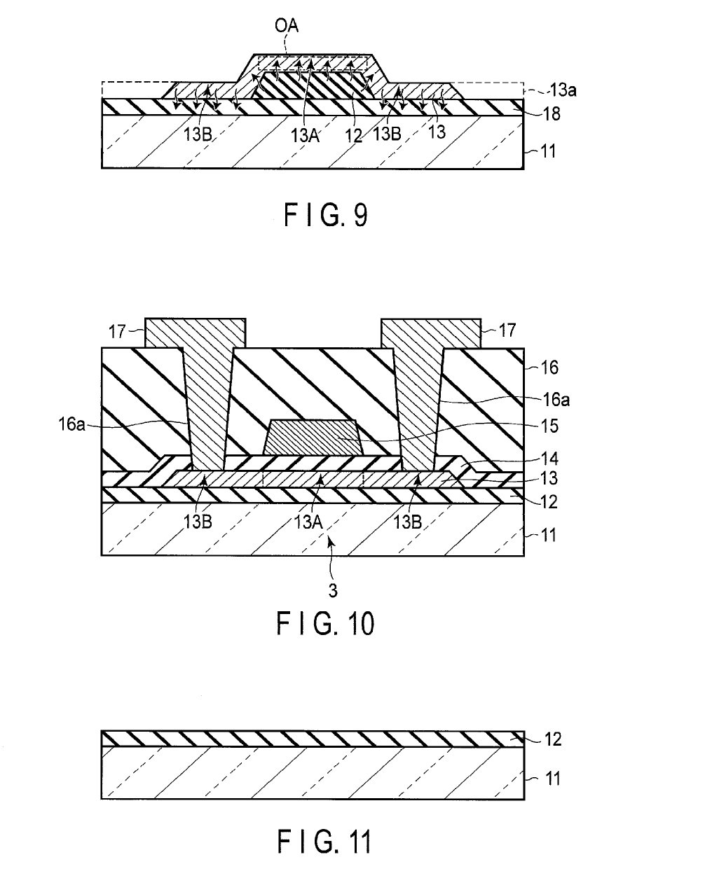

Next, as shown in FIG. 9, a semiconductor layer 13a formed from an oxide of at least one of indium (In), gallium (Ga) and zinc (Zn), for example, is provided all over the nitride insulating layer 18 using, for example, a sputtering method. The sputtering is performed, for example, in an inert gas atmosphere.

Then, the semiconductor layer 13a formed of an oxide is etched to form the semiconductor layer 13 which covers the first insulating layer 12 and is patterned into, for example, an island-like shape. The semiconductor layer 13 includes a region in contact with the first insulating layer 12 and another region in contact with the nitride insulating layer 18.

Next, the semiconductor layer 13 is subjected to heat treatment. Thus, oxygen contained in the first insulating layer 12 is supplied to the overlapping area OA of the semiconductor layers 13, which is overlaid on the first insulating layer 12. That is, oxygen diffuses to the semiconductor layer 13 from the first insulating layer 12 which has an oxygen concentration higher than that of the semiconductor layer 13. As a result, the oxygen defect in the semiconductor layer 13 formed of the oxide is supplemented, and thus the channel regions 13A having high oxygen concentration and high resistance is formed.

On the other hand, the oxygen concentration of the nitride insulating layer 18 is lower than that of the semiconductor layer 13. Therefore, oxygen contained to the region of the semiconductor layers 13, which is in contact with the nitride insulating layer 18 partially diffuses to the nitride insulating layer 18, thus reducing the semiconductor layer 13. As a result, the oxygen concentration of the region of the semiconductor layers 13, which is in contact with the nitride insulating layer 18, decreases and the source/drain regions 13B and 13B having a resistance lower than that of the channel regions 13A are formed. At this time, hydrogen contained in the nitride insulating layer 18 partially diffuses into the semiconductor layer 13.

After that, by processing steps similar to those of the first embodiment, a second insulating layer 14 as a gate insulating layer, a gate electrode 15, a third insulating layer 16, and source/drain electrodes 17 and 17 are formed as shown in FIG. 6.

An advantageous effect similar to that of the first embodiment can be obtained also in the second embodiment. Further, according to the second embodiment, the nitride insulating layer 18 is formed on the entire surface of the substrate 11, and therefore the oxygen concentration of the source/drain region 13B and 13B formed on the nitride insulating layer 18 is reduced. Therefore, as compared to the case where the nitride insulating layer 18 in contact with the semiconductor layer 13 is not formed, the resistance of the source/drain regions 13B and 13B, which are formed to correspond to the regions in contact with the nitride insulating layer 18 can be decreased. That is, the difference in resistance between the channel regions 13A made oxygen-rich by the first insulating layer 12 and the source/drain regions 13B and 13B where the oxygen concentration is decreased by the nitride insulating layer 18 can be enlarged. Thus, it becomes possible to suppress the leakage current of the thin film transistor and to obtain stable electrical characteristics.

### Third Embodiment

In the first and second embodiments, the first insulating layer 12 as an oxygen supply source is formed selectively in a region of the substrate 11, which corresponds to the channel region 13A of the thin film transistor.

By contrast, in the third embodiment, the first insulating layer 12 is formed on the entire surface of the substrate 11, and oxygen ions are implanted to only the region of the first insulating layers 12, which corresponds to the channel region 13A.

FIG. 10 is a cross section schematically showing a configuration example of a thin film transistor 3 according to the third embodiment.

As shown in FIG. 10, the first insulating layer 12 is formed on the entire surface of the substrate 11. The first insulating layer 12 may be formed from an oxide such as silicon oxide or aluminum oxide, or from an oxynitride such as silicon oxynitride or aluminum oxynitride. The semiconductor layer 13 is formed on the first insulating layer 12. The semiconductor layer 13 includes s channel region 13A and source/drain regions 13B and 13B which interpose the channel regions 13A therebetween. The semiconductor layer 13 is covered by the second insulating layer 14 which forms a gate insulating layer. The gate electrode 15 is formed in a position on the second insulating layer 14, which corresponds to the channel regions 13A. The other structure is the same as that of the first embodiment, the explanation therefor will be omitted.

Next, with reference to FIGS. 11 to 13, a method of manufacturing the thin film transistor 3 shown in FIG. 10 will be described.

As shown in FIG. 11, the first insulating layer 12 of, for example, silicon oxide is formed on an entire surface of the substrate 11 by, for example, the CVD method.

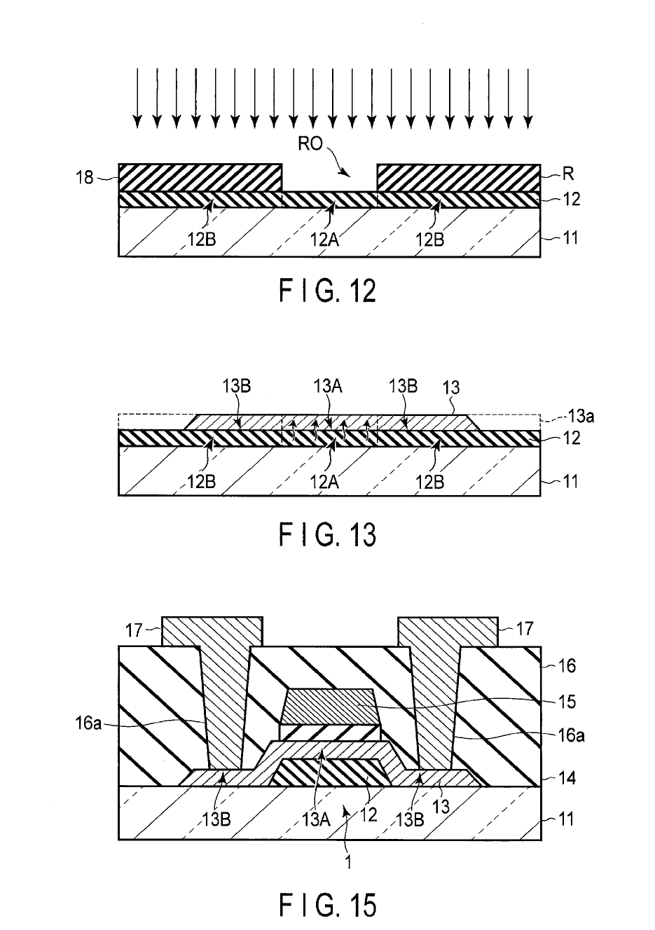

Next, as shown in FIG. 12, a resist layer R is formed on the first insulating layer 12. The resist layer R includes an opening RO in a position corresponding to the channel region 13A. Using the resist layer R as a mask, for example, oxygen ions are implanted to the first insulating layer 12. Thus, in a region of the first insulating layer 12, which is exposed by the opening RO, a first region (oxygen-excess region) 12A with high oxygen concentration is formed. On the other hand, in the other region of the first insulating layer 12, which is covered by the resist layer R, the second region 12B with an oxygen concentration lower than that of the first region 12A is formed.

Next, as shown in FIG. 13, the resist layer R is removed, and thereafter, a semiconductor layer 13a formed from an oxide of at least one of, for example, indium (In), gallium (Ga) and zinc (Zn), is provided on an entire surface of the first insulating layer 12 by, for example, the sputtering method. The sputtering is performed in, for example, an inert gas atmosphere. After that, the semiconductor layer 13a of an oxide is etched to form the semiconductor layer 13 patterned into, for example, an island-like shape. Here, the semiconductor layer 13 is formed so as to be in contact with at least the first region 12A and the second regions 12B and 12B on both sides of the first region 12A, of the first insulating layer 12.

Next, the semiconductor layer 13 is subjected to heat treatment. Thus, oxygen contained in the first region 12A is supplied to the region of the semiconductor layer 13, which is in contact with the first region 12A of the first insulating layer 12. In other words, oxygen diffuses into the semiconductor layer 13 from the first region 12A due to the gradient in oxygen concentration between the semiconductor layer 13 and the first region 12A having an oxygen concentration higher than that of the semiconductor layer 13. As a result, in the region of the semiconductor layers 13, which is in contact with the first region 12A, the oxygen defect in the semiconductor layer 13 is supplemented and the channel regions 13A are formed.

On the other hand, the oxygen concentration gradient between the second regions 12B and the semiconductor layer 13 is less than that between the first region 12A and the semiconductor layer 13. Therefore, in the regions of the semiconductor layer 13, which are in contact with the second regions 12B, less oxygen diffuses from the first insulating layer 12 into the semiconductor layer 13, which decreases the ratio of supplementing the oxygen defect in the semiconductor layer 13. As a result, in the regions of the semiconductor layer 13, which are in contact with the second regions 12B, the source/drain regions 13B having an oxygen concentration and resistance lower than those of the channel region 13A are formed.

After that, by processing steps similar to those of the first embodiment, a second insulating layer 14 as a gate insulating layer, a gate electrode 15, a third insulating layer 16, and source/drain electrodes 17 and 17 are formed as shown in FIG. 10.

According to the third embodiment, the first region 12A, which is an oxygen excess region, is formed in a region of the first insulating layer 12, which corresponds to the channel regions 13A, so that oxygen is supplied to the semiconductor layer 13 from the first region 12A as the oxygen supply source. With this structure, the oxygen defect in the semiconductor layer 13 can be selectively supplemented, and thus the channel regions 13A which have necessary and sufficient resistance can be formed in the semiconductor layer 13 as in the first and second embodiments.

Moreover, using the resist layer R as a mask, oxygen ions are implanted to the first insulating layer 12 and therefore the oxygen implantation area can be limited. For this reason, the oxygen concentration of the first region 12A of the first insulating layer 12, which corresponds to the channel region 13A, and that of the second regions 12B corresponding to the source/drain regions 13B and 13B are reliably controlled. Therefore, the oxygen defect in the semiconductor layer 13 can be selectively supplemented, and thus it is possible to reduce the variation in electrical characteristics of the thin film transistor, including the threshold voltage and the like.

### Examples of Application

Display devices can be manufactured using the thin film transistors described in the first, second and third embodiment, respectively.

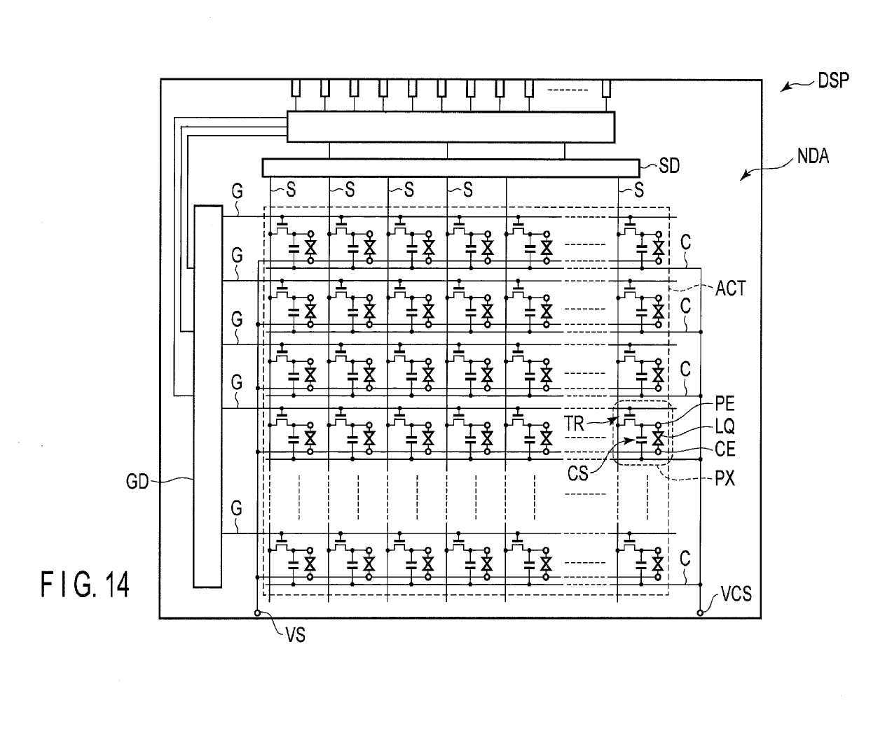

FIG. 14 schematically shows a configuration example of a display device DSP comprising a thin film transistor TR described in the first, second or third embodiment. In this example, the display device DSP is a liquid crystal display containing the liquid crystal elements, for example. However, the thin film transistors TR illustrated in the first, second and third embodiment may be applicable not only to liquid crystal displays but also to organic electroluminescence (EL) display devices, other self-luminous display devices, electronic-paper-type display devices containing an electrophoretic element, and all types of flat-panel display devices, etc.

As shown in FIG. 14, the display device DSP comprises an active area (display area) ACT which displays images and a non-display area (peripheral circuit area) NDA located on an outer side of the active area ACT. The active area ACT includes a number of pixels PXs arranged along row and column directions, for example. The display device DSP comprises a number of gate lines G extending in the row direction, a number of capacitance lines C extending respectively alongside and parallel to the gate lines G, and a number of signal lines S extending in the column direction intersecting the gate lines G and capacitance lines C.

The non-display area NDA comprises a gate driver GD, a source driver SD, a voltage applying module VCS, a power supply module VS and the like. Each gate line G extends out of the active area ACT so as to be connected to the gate driver GD. Each source line S extends out of the active area ACT so as to be connected to the source driver SD. Each capacitance line C extends out of the active area ACT so as t be connected to the voltage applying module VCS.

Each pixel PX comprises a thin film transistor TR, a capacitor CS, a pixel electrode PE, a common electrode CE and a liquid crystal layer LQ provided between the pixel electrode PE and the common electrode CE. The thin film transistor TR is a transistor having a structure described in the first, second or third embodiment. The gate electrode of the thin film transistor TR is connected to the respective gate line G. The first electrode (source electrode 17) of the thin film transistor TR is connected to the respective source line S, and the second electrode (drain electrode 17) of the thin film transistor TR is connected to the first electrode of the capacitor CS and the pixel electrode PE. The second electrode of the capacitor CS is connected to the respective capacitance line C. The common electrode CE is connected to the power supply module VS provided outside the active area ACT.

Note that the thin film transistor illustrated in the first, second or third embodiment may be used for a circuit which constitutes the gate driver GD, source driver SD and the like, of the display device DSP.

According to the display device DSP comprising the thin film transistor TR, a light-caused leakage current can be suppressed and the area in which a thin film transistor is placed can be decreased as compared to display devices which employ a silicon-semiconductor for the thin film transistor. Therefore, the power consumption can be reduced, and the opening area which contributes to display can be expanded in each pixel PX.

### Modified Example

FIG. 15 is a cross-section showing another example of the first embodiment. In the thin film transistor 1, the second insulating layer 14 may be formed directly under the gate electrode 15, that is, only the region overlapping the first insulating layer 12, as shown in FIG. 15. In this case, when the second insulating layer 14 is formed of an oxide, oxygen diffuses from the first insulating layer 12 and the second insulating layer 14 into the channel region 13A of the semiconductor layer 13. On the other hand, since the source/drain regions 13B and 13B are not substantially in contact with the first insulating layer 12 and the second insulating layer 14, the amount of oxygen diffusing into the source/drain regions 13B and 13B is sufficiently small as compared to that of the channel region 13A. Therefore, according to this example, the difference in oxygen concentration between the channel region 13A and the source/drain regions 13B and 13B, that is, the difference in resistance, can be enlarged. As a result, it becomes possible to suppress the leakage current of the thin film transistor and to obtain the stable electrical characteristics.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a thin film transistor, comprising:
forming an island-like first insulating layer containing oxygen above an insulating substrate;
forming an oxide semiconductor layer above the insulating substrate and the first insulating layer and in contact with the first insulating layer; and
performing heat treatment to supply oxygen from the first insulating layer to an overlapping area of the oxide semiconductor layer, which is overlaid on the first insulating layer.

2. The manufacturing method of claim 1, wherein
the oxide semiconductor layer is in contact with the insulating substrate, and
a diffusion coefficient of oxygen in the insulating substrate is lower than that in the first insulating layer.

3. The manufacturing method of claim 2, wherein
an oxygen concentration of a portion of the oxide semiconductor layer, which is in contact with the first insulating layer after the heat treatment is higher than that of a portion of the oxide semiconductor layer, which is in contact with the insulating substrate.

4. The manufacturing method of claim 1, further comprising:
forming a second insulating layer in at least a region on the oxide semiconductor layer, which overlaps the first insulating layer; and
forming a gate electrode on the second insulating layer.

5. The manufacturing method of claim 4, wherein
the first insulating layer and the second insulating layer are each formed of an oxide.

6. The manufacturing method of claim 1, wherein
the first insulating layer is formed of an oxide or an oxynitride, and
oxygen ions are implanted to the first insulating layer before forming the oxide semiconductor layer.

7. The manufacturing method of claim 1, further comprising:
forming a nitride insulating layer on the insulating substrate before forming the first insulating layer, and
wherein
the oxide semiconductor layer is in contact with the nitride insulating layer.

8. The manufacturing method of claim 7, wherein
an oxygen concentration of a portion of the oxide semiconductor layer, which is in contact with the first insulating layer after the heat treatment is higher than that of a portion of the oxide semiconductor layer, which is in contact with the nitride insulating layer.

9. The manufacturing method of claim 1, wherein
the oxide semiconductor layer is formed of an oxide containing at least one of indium, gallium and zinc.

10. A method of manufacturing a thin film transistor, comprising:
forming a first insulating layer of an oxide or an oxynitride above an insulating substrate;
forming, above the first insulating layer, a resist layer including an opening;
implanting oxygen ions to the first insulating layer using the resist layer as a mask;
forming an oxide semiconductor layer on the first insulating layer after removing the resist layer; and
performing heat treatment to supply oxygen from the first insulating layer to the oxide semiconductor layer.

11. The manufacturing method of claim 10, wherein
the first insulating layer, after the implantation of oxygen ions, includes a first region exposed by the opening, in which the oxygen ions are implanted, and a second region covered with the resist layer and having an oxygen concentration lower than that of the first region, and
after the heat treatment, an oxygen concentration of a portion of the oxide semiconductor layer, which is in contact with the first region is higher than that of a portion of the oxide semiconductor layer, which is in contact with the second region.

12. The manufacturing method of claim 11, further comprising:
forming a second insulating layer in at least a region on the oxide semiconductor layer, which overlaps the first region; and
forming a gate electrode on the second insulating layer.

13. The manufacturing method of claim 12, wherein
the first insulating layer and the second insulating layer are each formed of an oxide.

14. The manufacturing method of claim 10, wherein
the oxide semiconductor layer is formed of an oxide containing at least one of indium, gallium and zinc.

15. A thin film transistor comprising:
an island-like first insulating layer provided above an insulating substrate;
an oxide semiconductor layer located above the insulating substrate and the first insulating layer and being in contact with the first insulating layer;
a second insulating layer provided on the oxide semiconductor layer; and
a gate electrode provided on the second insulating layer,
the oxide semiconductor layer comprising a channel region provided on the first insulating layer, and a source region and a drain region interposing the channel region therebetween.

16. The thin film transistor of claim 15, wherein
the oxide semiconductor layer is in contact with the insulating substrate.

17. The thin film transistor of claim 16, wherein
an oxygen concentration of a portion of the oxide semiconductor layer, which is in contact with the first insulating layer is higher than that of a portion of the oxide semiconductor layer, which is in contact with the insulating substrate.

18. The thin film transistor of claim 15, further comprising:
a nitride insulating layer located between the insulating substrate and the first insulating layer, and
wherein
the oxide semiconductor layer is in contact with the nitride insulating layer.

19. The thin film transistor of claim 18, wherein
an oxygen concentration of a portion of the oxide semiconductor layer, which is in contact with the first insulating layer is higher than that of a portion of the oxide semiconductor layer, which is in contact with the nitride insulating layer.

20. The thin film transistor of claim 15, wherein
the first insulating layer and the second insulating layer are each formed of an oxide.
